(19) United States
(12) Patent Application Publication
(10) Pub. No.: US 2026/0035792 A1
(43) Pub. Date: Feb. 5, 2026

(54) DEPOSITING CARBON FILMS USING A SINGLE PRECURSOR

(71) Applicant: Micron Technology, Inc., Boise, ID (US)

(72) Inventors: Jean-Sebastien Materne Lehn, Boise, ID (US); Enrico Varesi, Milano (MI) (IT); Parameswara Subramanian, Meridian, ID (US); Farrell M. Good, Meridian, ID (US)

(21) Appl. No.: 19/280,997

(22) Filed: Jul. 25, 2025

Related U.S. Application Data
(60) Provisional application No. 63/677,831, filed on Jul. 31, 2024.

(51) Int. Cl. C23C 16/455; C23C 16/26

(52) U.S. Cl. CPC C23C 16/45553; C23C 16/26; C23C 16/45527

(57) ABSTRACT

Methods, systems, and devices for depositing carbon films using a single precursor are described. ALD may be performed by reacting a single precursor with a base material over multiple ALD cycles to thermally deposit a layer of carbon on the base material. For instance, each of the ALD cycles may include reacting a carbon-containing precursor with the base material in a chamber and performing a purge operation to remove contaminant materials (e.g., side products of the reaction, at least portions of the single precursor) from the chamber.

### CROSS REFERENCE

The present Application for Patent claims priority to U.S. Patent Application No. 63/677,831 by Lehn et al., entitled “DEPOSITING CARBON FILMS USING A SINGLE PRECURSOR,” filed Jul. 31, 2024, which is assigned to the assignee hereof, and which is expressly incorporated by reference in its entirety herein.

### FIELD OF TECHNOLOGY

The following relates to methods for performing atomic layer deposition, including depositing carbon films using a single precursor.

### BACKGROUND

Atomic layer deposition (ALD) is a technique used to deposit a film in which the film grows on a base material layer by layer (e.g., with atomic-level layer thickness). Typically, multiple precursors are used that react with the surface of the material one at a time in a sequential, self-limiting, manner. For instance, performing ALD may include exposing the material to a first precursor to form a first compound on the material. Additionally, performing ALD may include exposing the material (e.g., with the layer of the first compound) to a second precursor, where the second precursor may react with the first compound to leave a second compound on the surface of the material. In some examples, the process may repeat, where the second compound may be exposed to the first precursor to form another instance of the first compound on the material, and then the other instance of the first compound may be exposed to the second precursor to leave another instance of the second compound on the surface of the previously formed instance of the second compound.

In some examples, reactions involved in ALD may produce various contaminant materials (e.g., side products) which may adversely affect an operation of an electronic device that includes these contaminant materials (e.g., may decrease a lifetime of the electronic device, may increase a likelihood that the electronic device displays errant behavior or does not perform its intended function). For example, in some cases contaminant materials (e.g., silicon) may increase the resistivity of conductive films (e.g., carbon films) within an electronic device.

### BRIEF DESCRIPTION OF THE DRAWINGS

FIG. 1 illustrates an example of an atomic layer deposition (ALD) process that supports depositing carbon films using a single precursor in accordance with examples as disclosed herein.

FIG. 2 illustrates an example of a material formation process that supports depositing carbon films using a single precursor in accordance with examples as disclosed herein.

FIG. 3 illustrates an example of an electronic device that supports depositing carbon films using a single precursor in accordance with examples as disclosed herein.

FIGS. 4 and 5 show flowcharts illustrating a method or methods that support depositing carbon films using a single precursor in accordance with examples as disclosed herein.

FIG. 6 shows an example of a memory array that supports methods for depositing carbon conducting films in accordance with examples as disclosed herein.

FIG. 7 shows a top view of an example of a memory array that supports methods for depositing carbon conducting films in accordance with examples as disclosed herein.

FIGS. 8A and 8B show side views of an example of a memory array that supports methods for depositing carbon conducting films in accordance with examples as disclosed herein.

### DETAILED DESCRIPTION

An electronic device may be made by manipulating layers of materials to form various conductive, dielectric, and semiconductive structures. One technique for adding layers to the electronic device is to perform atomic layer deposition (ALD). In some examples, it may be advantageous for one or more of those layers to be made up of carbon with a purity above a threshold amount (e.g., 85% pure carbon, 90% pure carbon, 95% pure carbon, 99% pure carbon, 99.9% pure carbon). For instance, carbon with the purity above the threshold amount may have conductive properties that may enhance the operation of the electronic device (e.g., such carbon may have a higher conductivity as compared to other materials). However, previously disclosed precursors and techniques used in ALD, such as an ALD which uses two different precursors reacted in sequence, have not been shown to be capable of producing such carbon. For example, the use of two different precursors for ALD may result in the deposition of other elements or compounds with the carbon.

In accordance with examples described herein, ALD may be performed by reacting a single precursor with a base material over multiple ALD cycles to thermally deposit a layer of carbon on the base material. For instance, each of the ALD cycles may include reacting a carbon-containing precursor with the base material in a chamber and performing a purge operation to remove contaminant materials (e.g., side products of the reaction, at least portions of the single precursor) from the chamber. By performing ALD with a single precursor, a carbon layer may be formed with purity above the threshold amount for an electronic device, which may increase a conductivity of carbon films within the electronic device, thereby increasing reliability and accuracy of operations performed by the electronic device in accordance with its intended function.

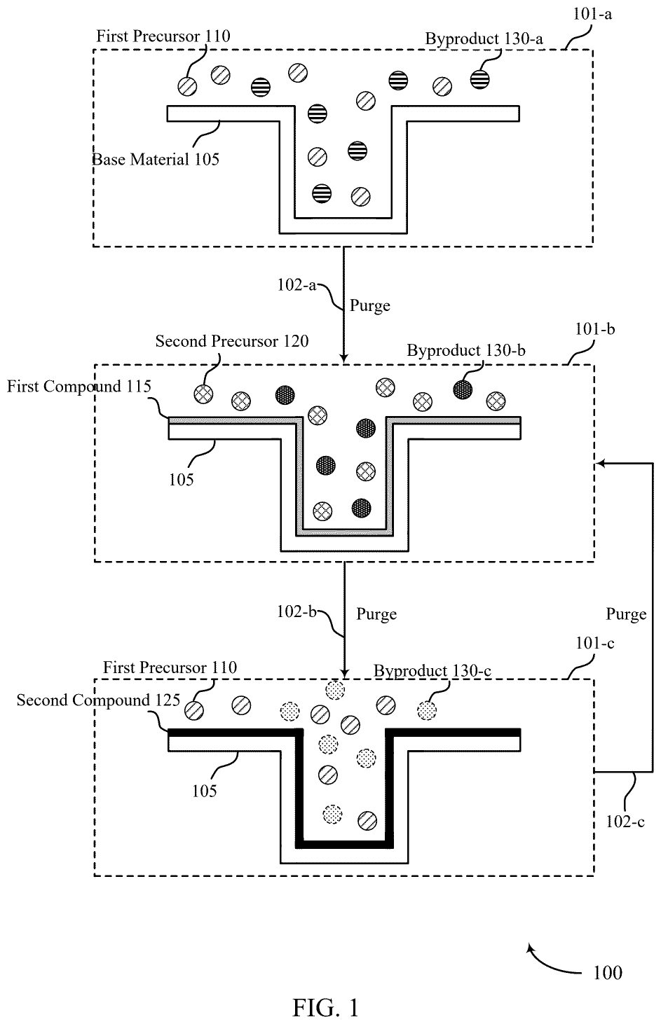

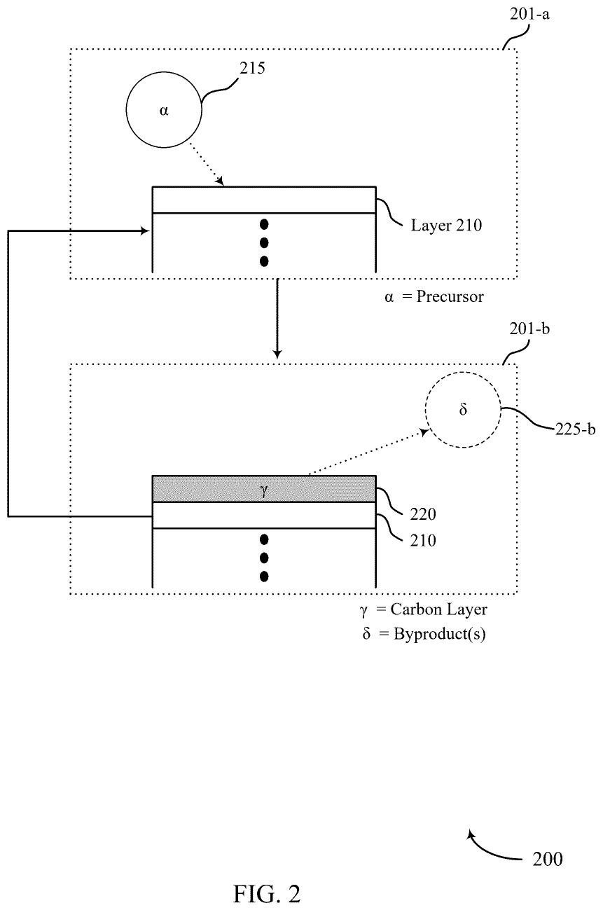

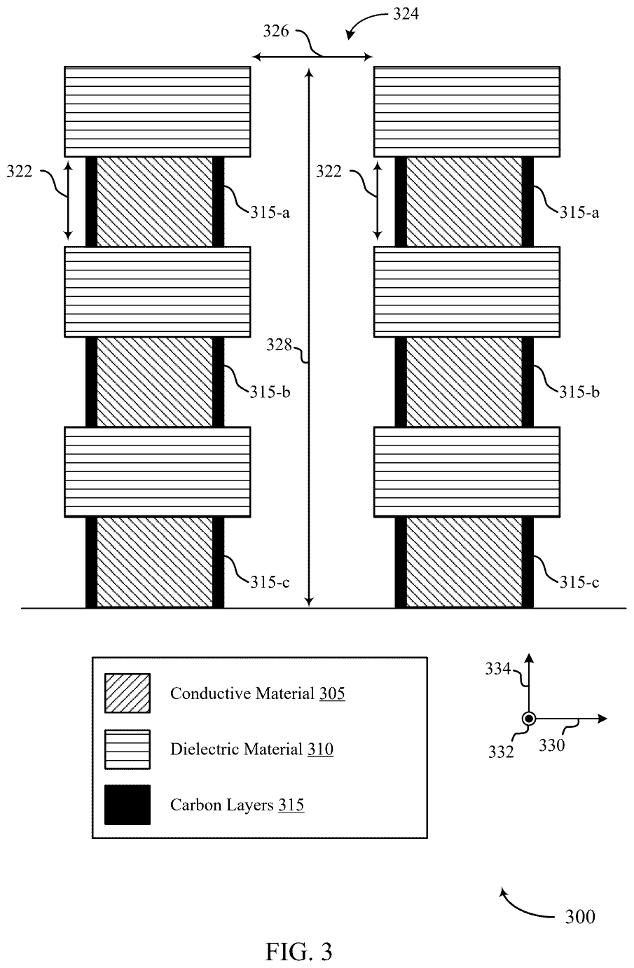

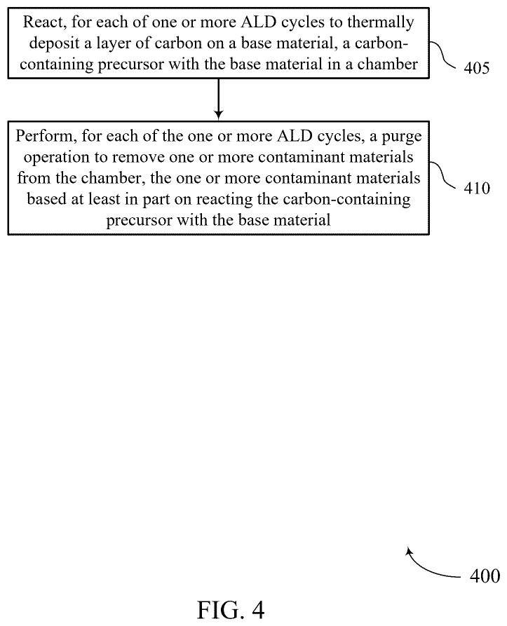

Features of the disclosure are initially described in the context of an ALD process and a material formation process as described with reference to FIGS. 1 and 2. Features of the disclosure are described in the context of an electronic device as described with reference to FIG. 3. These and other features of the disclosure are further illustrated by and described with reference to flowcharts and memory arrays that relate to depositing carbon films using a single precursor as described with reference to FIGS. 4 through 8B.

FIG. 1 illustrates examples of an ALD process 100 that supports depositing carbon films using a single precursor in accordance with examples as disclosed herein.

As illustrated in stage 101-a, a base material 105 may be exposed to a first precursor 110. For instance, the base material 105 may be located in a reactor (e.g., deposition chamber) within which a gaseous phase of the first precursor 110 may be introduced. Exposing the base material to the first precursor may enable a first compound 115 to form on the surface of the base material 105, as depicted in stage 101-b. In some examples, as a result of the reaction between base material 105 and first precursor 110, a byproduct 130-a will be formed. After forming first compound 115, the byproduct 130-a and/or a portion of the first precursor 110 may be purged (e.g., removed from the reactor) at the purge 102-a before proceeding to stage 101-b. In some examples, the temperature of the reactor may be set or adjusted to a first predefined value such that the first compound 115 forms on the surface of the base material 105.

In some examples, the base material may be a substrate, which may be an exposed surface (e.g., material) for facilitating reactions with the precursor. The substrate may be a dielectric material or a metal material (e.g., tungsten), such as a word line or a bit line. In some examples, exposing the base material to a precursor may refer to adding the precursor to the reactor within which the base material is located. The precursor may be exposed to the precursor to facilitate a chemical reaction between the precursor and the base material. Exposing the base material to the precursor may involve setting or adjusting a temperature of the reactor to a particular temperature that facilitates the reaction.

After forming the first compound 115 at stage 101-a, the first compound 115 may be exposed to a second precursor 120 at stage 101-b. For instance, a gaseous phase of the second precursor 120 may be introduced into the reactor and exposed to the surface of the first compound 115. In some examples, the base material 105 may be transported to a second reactor for introducing the second precursor 120. In other examples, the same reactor may be used. The second precursor 120 may react with the first compound 115 to form a second compound 125, as shown in stage 101-b. In some examples, as a result of the reaction between first compound 115 and second precursor 120, a byproduct 130-b will be formed. After forming second compound 125, the byproduct 130-b and/or at least a portion of the second precursor 120 may be purged (e.g., removed from the reactor) at purge 102-b before proceeding to stage 101-c. In some examples, the temperature of the reactor may be set or adjusted to a second predefined value such that the second compound 125 forms on the surface of the base material 105.

After forming the second compound 125 at stage 101-b, the second compound 125 may be exposed to a first precursor 110 at stage 101-c. For instance, a gaseous phase of the first precursor 110 may be introduced to the reactor and exposed to the surface of the second compound 125. In some examples, the base material 105 may be transported to a third reactor for introducing the first precursor 110. In other examples, the same reactor may be used for stage 101-c as used for one or both of stages 101-a and 101-b. The first precursor 110 may react with the second compound 125 to form a second instance of the first compound 115 on top of the second compound 125. In some examples, as a result of the reaction between second compound 125 and first precursor 110, a byproduct 130-c will be formed. After forming the second instance of first compound 115, the byproduct 130-c and/or at least a portion of the first precursor 110 may be purged (e.g., removed from the reactor) at the purge 102-c before returning back to stage 101-b. In some examples, the temperature of the reactor may be set or adjusted to the first predefined value or a third predefined value such that the first compound 115 forms on the surface of the base material 105. In some examples, first precursor 110 and second precursor 120 may be delivered to the reactor (e.g., or reactors) using an inert gas (e.g., argon, helium, nitrogen). Additionally, or alternatively, the byproducts 130-a, 130-b and/or 130-c may be purged using an inert gas (e.g., argon, helium, nitrogen).

In some examples, the process may be repeated to deposit multiple layers of the second compound 125. For instance, after depositing a first instance of second compound 125, the first instance of the second compound 125 may be exposed to the first precursor 110 to form a second instance of the first compound 115 on a surface of the first instance of the second compound 125. Then, the second instance of the first compound 115 may be exposed to the second precursor 120 to form a second instance of the second compound 125 on the surface of the first instance of the second compound 125.

In some cases, by reacting the base material with the first precursor 110 and the second precursor 120, an amount of the byproducts 130 may be relatively high and may reduce the purity of the second compound 125 which is formed on the base material 105 as a result of the ALD. For example, the first precursor 110 may be a silicon-containing compound, and the second compound 125 may have a relatively large amount (e.g., more than trace amounts) of silicon as a result of reacting the first precursor 110 with the base material 105.

In accordance with examples described herein, ALD may be performed using multiple ALD cycles of reacting a single precursor (e.g., the precursor 120) with the base material 105. For example, cycles of the ALD may include the stage 101-b and the purge 102-b alone, without introducing the first precursor 110 to the base material 105 (e.g., excluding the stage 101-a and the purge 102-a). At the stage 101-b, the base material may be exposed to the second precursor 120, which may be a carbon-containing precursor (e.g., carbon tetrabromide) for a first duration. In some examples, as a result of the reaction between the base material 105 and the second precursor 120, a byproduct 130-b will be formed. The byproduct 130-b may be bromine and may exclude silicon, oxygen, and hydrogen. After forming the second compound 125, which may be carbon (e.g., a carbon layer satisfying a purity threshold), the byproduct 130-b and/or at least a portion of the second precursor 120 may be purged (e.g., removed from the reactor) at the purge 102-b for a second duration before returning to the stage 101-b (e.g., for another cycle of the ALD). In some examples, the temperature of the reactor may be set or adjusted to a predefined value such that the second compound 125 forms on the surface of the base material 105 in response to a chemical reaction facilitated between the second precursor 120 and the base material 105 at the predefined temperature.

In some examples, the base material 105 may be a structure on a substrate (e.g., a wafer). In some such examples, the base material 105 may span in a first direction and a second direction, where the first direction is orthogonal to the second direction. Additionally, a memory device including the base material 105 may include word lines extending along the first direction and/or the second direction and bit lines extending along a third direction orthogonal to the first direction and the second direction. In some such examples, a stack of materials (e.g., a sequence of materials) may be formed that includes the base material 105. The stack of materials may include layers of a first material (e.g., conductive material, word lines, tungsten) and a second material (e.g., dielectric material). Recesses (e.g., cavities) may be formed in the stack of materials (e.g., in the layers of word lines) to expose surfaces of the first material (e.g., the word lines) and the second material. In some examples, the techniques described herein may be used to form layers of carbon on the exposed portions of the first material without forming layers of carbon on the exposed portions of the second material.

FIG. 2 illustrates an example of a material formation process 200 that supports depositing carbon films using a single precursor in accordance with examples as disclosed herein.

As illustrated in FIG. 2, a carbon layer 220 may be thermally deposited onto a layer 210 over one or more ALD cycles that include a reaction process 201-a and a purge process 201-b. During the reaction process 201-a, the layer 210 may be exposed to the precursor 215 (e.g., in a reactor, in a chamber), which may be a carbon-containing precursor (e.g., carbon tetrabromide). The reaction process 201-a may occur during a first duration (e.g., 25-180 seconds). Exposing the layer 210 to the precursor 215 (e.g., at a threshold temperature) may facilitate a chemical reaction between the layer 210 and the precursor 215. For example, the temperature of the reactor may be set or adjusted to a predefined value such that the carbon layer 220 forms on the surface of the layer 210 in response to the chemical reaction facilitated between the precursor 215 and the layer 210 at the predefined temperature (e.g., which may correspond to an activation energy for facilitating the reaction). The temperature of the reactor during the reaction process 201-a may be adjusted such that the layer 210 (e.g., a tungsten layer) is not etched by the precursor 215 but rather that the layer 210 reacts with the precursor 215 to deposit carbon.

In some examples, as a result of the reaction between the layer 210 and the precursor 215, a byproduct 225-b will be formed. The byproduct 130-b may be bromine and may exclude silicon, oxygen, and hydrogen. During the purge process 201-b, the byproduct 225-b and/or at least a portion of the precursor 215 may be purged (e.g., removed from the reactor, evacuated). The purge process 201-b may occur during a second duration (e.g., 30-50 seconds). In some examples, the byproduct 225-b may be purged using an inert gas (e.g., argon, helium, nitrogen). Additionally, or alternatively, the purge process 201-b may include purging (e.g., removing) the precursor 215 from exposure to the reactor. In some examples, after the purge process 201-b has completed (e.g., after the second duration), the material formation process 200 (e.g., the ALD) may return to the reaction process 201-a (e.g., for performing another cycle of the ALD).

The precursor 215 may be a carbon halide (e.g., carbon tetrabromide, tetrabromoethylene, hexabromoethane, hexabromobenzene, hexachloro benzene) or a polyhalogenated molecule (e.g., a carbon-containing compound that includes a combination of bromide, iodide, chloride, and/or fluoride substituents). The layer 210 may be a conductive material (e.g., tungsten). The carbon layer 220 formed by the single precursor ALD may satisfy a threshold purity (e.g., carbon with above 85% purity, carbon with above 90% purity, carbon with above 95% purity, carbon with above 99% purity, carbon with above 99.9% purity).

In some examples, the precursor 215 may be delivered to the reactor (e.g., or reactors) during the reaction process 201-a using an inert gas (e.g., argon, helium, nitrogen). For example, the precursor 215 may be delivered to the reactor in a gaseous phase. The precursor 215 may be delivered to the reactor at a first partial pressure and the inert gas may be delivered to the reactor at a second partial pressure. For example, the precursor 215 may be delivered to the reactor such that a partial pressure of the precursor 215 occupies (e.g., corresponds to) 1-6% of a total pressure of the reactor. A partial pressure of the inert gas (e.g., a carrier gas, helium) may occupy 20-30% of the total pressure of the reactor. In some examples, a partial pressure of a second inert gas (e.g., argon, a balance) may make up the remaining pressure of the reactor. A ratio between the first partial pressure of the precursor 215 and the second partial pressure of the inert gas may satisfy a threshold.

Additionally, or alternatively, the reaction between the precursor 215 and the layer 210 may be based on a concentration of the precursor 215 in the reactor during the reaction process 201-a. The precursor 215 may be delivered to the reactor at a first concentration (e.g., of a total concentration of feed materials that are delivered to the reactor) and the inert gas may be delivered to the reactor at a second concentration. For example, the precursor 215 may be delivered to the reactor such that a concentration of the precursor 215 occupies (e.g., corresponds to) 1-6% of a total concertation of feed materials delivered to the reactor (e.g., during the reaction process 201-a). A concentration of the inert gas (e.g., a carrier gas, helium) may occupy 20-30% of the total concentration of the feed materials. In some examples, a concentration of a second inert gas (e.g., argon, a balance) may make up the remaining concentration of the feed materials.

In some examples, the reaction process 201-a may include two steps, which may be referred to as a dose and a soak. The dose may include inserting the precursor 215 into the reactor with the layer 210. The dose may occur over a third duration (e.g., 10-60 seconds), which may be referred to as a dose time. In some examples, a concentration of the precursor 215 in the reactor may be directly proportional to the dose time. The soak may include allowing the precursor 215 to react with the layer 210 (e.g., without adding more of the precursor 215 to the reactor) during a fourth duration (e.g., 15-120 seconds), which may be referred to as a soak time. In some examples, the reaction of the precursor 215 with the layer 210 to form the carbon layer 220 may be based on the first duration (e.g., 25-180 seconds) associated with the reaction process 201-a, the second duration (e.g., 30-50 seconds) associated with the purge process 201-b, the third duration associated with the dose time, or the fourth duration associated with the soak time, or a combination thereof. For example, a thickness of the carbon layer 220 formed on the layer 210 may be based on a ratio between the first duration associated with the reaction process 201-a and the second duration associated with the purge process 201-b. In some examples, the first duration associated with reacting the precursor 215 with the layer 210 may be greater than the second duration associated with purging the contaminant materials from the reactor. Alternatively, the first duration associated with reacting the precursor 215 with the layer 210 may be less than the second duration associated with purging the contaminant materials from the reactor.

In some examples, the reaction process 201-a and the purge process 201-b may be repeated over a quantity of ALD cycles to deposit additional growth of carbon on the layer 210 (e.g., to produce a carbon layer 220 with a relatively greater thickness). In some examples, a thickness of the carbon layer 220 may be based on the quantity of ALD cycles performed.

In some examples, the material formation process 200 described herein may refer to a thermal ALD process, which may be different than a plasma ALD process. For example, the reaction process 201-a may be conducted at a first range of temperatures (e.g., 280° C. to 550° C.) different than a second (e.g., lower) range of temperatures associated with plasma ALD processes (e.g., below 280° C.). The temperature at which the reaction process 201-a is conducted may enable a thermal deposition of the carbon layer on the layer 210. For example, the temperature may be associated with an activation energy of one or more reactions to facilitate a bonding of carbon to the layer 210 (e.g., or to other carbon molecules, such as the carbon layer 220) in sp² mode.

In some examples, a lower bound of the first range of temperatures (e.g., a temperature sufficient to facilitate reactions to form carbon, a minimum temperature) may be based on (e.g., or indicated by) a presence of the byproducts 225 in the reactor (e.g., a threshold amount of the byproducts 225, a threshold partial pressure of the byproducts 225, a threshold concentration of the byproducts 225). For example, the thermal deposition of the carbon layer on the layer 210 (e.g., a relative success of the thermal deposition, a thickness of the carbon layer) may be based on a ratio between an amount (e.g., a partial pressure, a concentration) of the precursor 215 inserted into the reactor and an amount (e.g., a partial pressure, a concentration) of the byproducts 225 generated as a result of reacting the precursor 215 with the layer 210.

In some examples, an upper bound of the first range of temperatures (e.g., a maximum temperature) may be based on preventing undesirable reactions of the precursor 215 with other compounds (e.g., walls of the chamber, dielectric materials, etc.), which may be associated with an increased likelihood that the byproducts 225 (e.g., contaminants) are present in the carbon film (e.g., causing the carbon film to drop below a threshold purity). Additionally, or alternatively, these and other undesirable reactions, which may be facilitated at relatively high temperatures (e.g., above the upper bound) may cause break down (e.g., corrosion, damage) to the layer 210, to the reactor, or to other structures.

The methods described herein may have one or more advantages. For instance, using the single precursor 215 as described herein for ALD may enable the carbon content of the carbon layer 220 to be as high as 85%, 90%, 95%, 99%, 99.9%, or 100%, may enable a deposited film to contain up to 75%, 85%, 90%, 95%, 99%, 99.9%, or 100% sp² carbon, and/or may enable that the carbon film deposited by ALD is conformal within high-aspect cavities of 3D structures (e.g., deep 3D structures, such as 3D structures with a depth above a threshold amount or aspect ratio higher than a threshold).

FIG. 3 illustrates an example of an electronic device 300 that supports depositing carbon films using a single precursor in accordance with examples as disclosed herein. The electronic device 300 may include a stack of layers. The stack of layers may include a first set of layers of a conductive material 305 and a second set of layers of a dielectric material 310. In accordance with examples described herein, a carbon layer 315 may be selectively deposited onto surfaces of the conductive material 305 (e.g., within cavities 322 formed in the stack of layers) without being formed onto surfaces of the dielectric material 310. The dielectric material 310 may be an example of a Silicon dioxide, a nitride, an oxide, Barium titanate, Hafnium silicate, or Zirconium silicate, among others. The conductive material 305 may be a metal material (e.g., tungsten) and may be an example of a base material 105 as described with reference to FIG. 1 or a layer 210 as described with reference to FIG. 2. The carbon layers 315 may be examples of a second compound 125 as described with reference to FIG. 1 or a carbon layer 220 as described with reference to FIG. 2.

The layers of dielectric material 310 may be separated from each other by cavities 322. The materials of the dielectric material 310 may be formed adjacent to (e.g., over) the conductive material 305 using techniques such as photolithography, physical vapor deposition (PVD), chemical vapor deposition (CVD), or ALD. In some examples, the conductive material 305 may include one or more materials, layers, structures, or regions thereon. The stack of layers of electronic device 300 may be considered to be a high aspect ratio (HAR) structure, where HAR may for instance correspond to greater than or equal to an aspect ratio of dimensions of cavities (e.g., cavities 322 or 324) of 10:1, greater than or equal to an aspect ratio of 20:1, greater than or equal to an aspect ratio of 25:1, or greater than or equal to an aspect ratio of 50:1. For example, a HAR structure may have an aspect ratio of a depth dimension 328 to an opening dimension 326 that satisfies a threshold. In accordance with examples described herein using a single precursor ALD, the carbon layers 315 may be formed on the conductive material 305 (e.g., on each exposed surface of the conductive material 305) but not on the dielectric material 310 (e.g., exposed surfaces of the dielectric material 310).

The carbon layers 315 may be formed on the conductive material 305 according to the aspects described herein. For instance, the carbon layer 315 may be formed by performing a quantity of ALD cycles as described herein, where each ALD cycle includes exposing the electronic device 300 to a single precursor and purging a reaction chamber of contaminant materials. In some examples, the quantity of ALD cycles may be adjusted to selectively deposit the carbon on the conductive material 305 without growth of carbon on the dielectric material 310. For example, the quantity of ALD cycles may be lower than (e.g., may fail to satisfy) a growth delay for carbon on the dielectric material 310. In some examples, the ALD may be terminated (e.g., and no additional ALD cycles performed) prior to a start of nucleation of the carbon associated with the dielectric material 310 (e.g., prior to a nucleation density of the carbon on the dielectric material 310 surpassing a threshold for growth on the dielectric material 310). The carbon layer 315 may function as a conductive component of an electronic device 300, such as a portion of an element such as a transistor, a capacitor, or memory cell. For example, the carbon layer 315 may form an electrode, an etch-stop material, a gate, a barrier material, or a spacer material. One or more materials and/or structure (e.g., memory materials), such as a phase change material, magnetoresistive material, or ferroelectric material may subsequently be formed in the cavities 322 by techniques such as photolithography, PVD, CVD, or ALD and/or additional process acts conducted to form a complete electronic device containing the structure shown in electronic device 300.

The carbon layers 315 may be conformally formed on the conductive material 305 according to the aspects described herein. For instance, the thickness of carbon layers 315 on the exposed surfaces of the conductive material 305 may be substantially uniform. The carbon layer 315-a, the carbon layer 315-b, and the carbon layer 315-c may have respective thicknesses that are within a threshold thickness of one another (e.g., approximately the same thickness). For instance, the carbon layers 315 may be formed to a thickness ranging from a monolayer to 100 nm. Alternatively, the carbon layers 315 may be formed at a greater thickness. The carbon layers 315 may be in direct contact with the conductive material 305. Additionally, or alternatively, the carbon layer 315 may be in contact with only portions of the dielectric material 310.

In some examples, the conductive material 305 may be a structure on a substrate (e.g., a wafer). In some such examples, the conductive material 305 may span in a first direction and a second direction, where the first direction is orthogonal to the second direction. Additionally, a memory device including the conductive material 305 may include word lines (e.g., conductive material 305) extending along the first direction (e.g., x-direction 330) and/or the second direction (e.g., y-direction 332) and bit lines (not shown) extending along a third direction (e.g., z-direction 334) orthogonal to the first direction and the second direction. In some such examples, a stack of materials (e.g., a sequence of materials) may be formed. The stack of materials may include a first material (e.g., conductive material 305, word lines, tungsten) and a second material (e.g., dielectric material 310). Recesses (e.g., cavities 322) may be formed in the stack of materials (e.g., in the layers of word lines) to expose a surface of the conductive material 305 and sidewalls of the dielectric material 310. In some examples, the techniques described herein may be used to form carbon layers 315 on the conductive material 305 without forming layers of carbon on the dielectric material 310.

FIG. 4 shows a flowchart illustrating a method 400 that supports depositing carbon films using a single precursor in accordance with examples as disclosed herein. The operations of method 400 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 405, the method may include reacting, for each of one or more ALD cycles to thermally deposit a layer of carbon on a base material, a carbon-containing precursor with the base material in a chamber.

At 410, the method may include performing, for each of the one or more ALD cycles, a purge operation to remove one or more contaminant materials from the chamber, the one or more contaminant materials based at least in part on reacting the carbon-containing precursor with the base material.

In some examples, an apparatus (e.g., a manufacturing system) as described herein may perform a method or methods, such as the method 400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method or apparatus including operations, features, circuitry, logic, means, or instructions, or any combination thereof for performing one or more atomic layer deposition (ALD) cycles to thermally deposit a layer of carbon on a base material, each of the one or more ALD cycles including; reacting a carbon-containing precursor with the base material in a chamber; and performing a purge operation to remove one or more contaminant materials from the chamber, the one or more contaminant materials based at least in part on reacting the carbon-containing precursor with the base material.
Aspect 2: The method or apparatus of aspect 1, where reacting the carbon-containing precursor with the base material includes operations, features, circuitry, logic, means, or instructions, or any combination thereof for inserting the carbon-containing precursor to the chamber with the base material and a carrier gas, where the carbon-containing precursor is associated with a first partial pressure and the carrier gas is associated with a second partial pressure different from the first partial pressure.
Aspect 3: The method or apparatus of any of aspects 1 through 2, where reacting the carbon-containing precursor with the base material includes conducting the reacting at a temperature at or above 280° C.
Aspect 4: The method or apparatus of aspect 3, where the temperature is at or below 550° C.
Aspect 5: The method or apparatus of any of aspects 1 through 4, where reacting the carbon-containing precursor with the base material is based at least in part on a concentration of the carbon-containing precursor.
Aspect 6: The method or apparatus of any of aspects 1 through 5, where each of the one or more ALD cycles includes operations, features, circuitry, logic, means, or instructions, or any combination thereof for reacting the carbon-containing precursor with the base material for a first duration and performing the purge operation to remove the one or more contaminant materials for a second duration different than the first duration.
Aspect 7: The method or apparatus of aspect 6, where over the first duration, a ratio between a first amount of the carbon-containing precursor that is reacted with the base material and a second amount of the one or more contaminant materials satisfies a threshold.
Aspect 8: The method or apparatus of any of aspects 1 through 7, where the layer of carbon forms one or more sp² bonds with the base material based at least in part on reacting the carbon-containing precursor with the base material.
Aspect 9: The method or apparatus of any of aspects 1 through 8, where each of the one or more ALD cycles consists of reacting the carbon-containing precursor with the base material in the chamber and performing the purge operation to remove the one or more contaminant materials from the chamber.
Aspect 10: The method or apparatus of any of aspects 1 through 9, where the one or more ALD cycles are based at least in part on a thermal ALD process.
Aspect 11: The method or apparatus of any of aspects 1 through 10, where the carbon-containing precursor includes carbon tetrabromide.
Aspect 12: The method or apparatus of any of aspects 1 through 11, where the base material includes tungsten.
Aspect 13: The method or apparatus of any of aspects 1 through 12, where the one or more contaminant materials include bromine and exclude silicon, oxygen, and hydrogen.

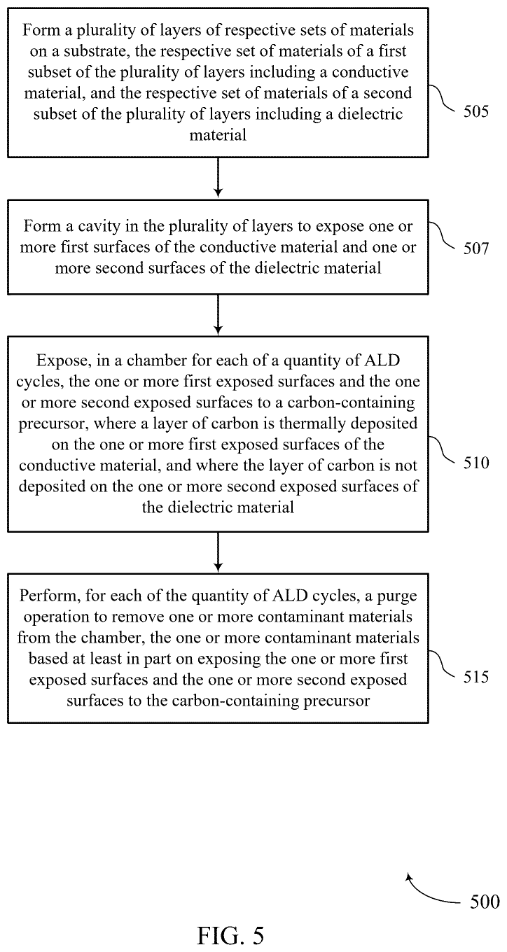

FIG. 5 shows a flowchart illustrating a method 500 that supports depositing carbon films using a single precursor in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include forming a plurality of layers of respective sets of materials on a substrate, the respective set of materials of a first subset of the plurality of layers including a conductive material and a memory material, and the respective set of materials of a second subset of the plurality of layers including a dielectric material.

At 507, the method may include forming a cavity in the plurality of layers to expose one or more first surfaces of the conductive material and one or more second surfaces of the dielectric material.

At 510, the method may include exposing, in a chamber for each of a quantity of ALD cycles, the one or more first surfaces and the one or more second surfaces to a carbon-containing precursor, where a layer of carbon is thermally deposited on the one or more first surfaces of the conductive material, and where the layer of carbon is not deposited on the one or more second surfaces of the dielectric material.

At 515, the method may include performing, for each of the quantity of ALD cycles, a purge operation to remove one or more contaminant materials from the chamber, the one or more contaminant materials based at least in part on exposing the one or more first surfaces and the one or more second surfaces to the carbon-containing precursor.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 14: A method or apparatus including operations, features, circuitry, logic, means, or instructions, or any combination thereof for forming a plurality of layers on a substrate, a first subset of the plurality of layers comprising a conductive material and a second subset of the plurality of layers comprising a dielectric material; forming a cavity in the plurality of layers to expose one or more first surfaces of the conductive material one or more second surfaces of the dielectric material; exposing, in a chamber for each of a quantity of atomic layer deposition (ALD) cycles, the one or more first surfaces and the one or more second surfaces to a carbon-containing precursor, where a layer of carbon is thermally deposited on the one or more first surfaces of the conductive material, and where the layer of carbon is not deposited on the one or more second surfaces of the dielectric material; and performing, for each of the quantity of ALD cycles, a purge operation to remove one or more contaminant materials from the chamber, the one or more contaminant materials based at least in part on exposing the one or more first surfaces and the one or more second surfaces to the carbon-containing precursor.
Aspect 15: The method or apparatus of aspect 14, where exposing the one or more first surfaces and the one or more second surfaces to the carbon-containing precursor includes operations, features, circuitry, logic, means, or instructions, or any combination thereof for inserting the carbon-containing precursor to the chamber with the one or more first surfaces and the one or more second surfaces and a carrier gas, where the carbon-containing precursor is associated with a first partial pressure and the carrier gas is associated with a second partial pressure different from the first partial pressure.
Aspect 16: method or apparatus of any of aspects 14 through 15, where exposing the one or more first surfaces and the one or more second surfaces to the carbon-containing precursor includes exposing the exposed areas of the plurality of layers in the chamber to a temperature at or above 280° C.
Aspect 17: The method or apparatus of aspect 16, where the temperature is at or below 550° C.
Aspect 18: The method or apparatus of any of aspects 14 through 17, where exposing the one or more first surfaces and the one or more second surfaces to the carbon-containing precursor is based at least in part on a concentration of the carbon-containing precursor.
Aspect 19: The method or apparatus of any of aspects 14 through 18, where each of the quantity of ALD cycles includes operations, features, circuitry, logic, means, or instructions, or any combination thereof for reacting the carbon-containing precursor with the one or more first surfaces and the of the conductive material in the chamber for a first duration and performing the purge operation to remove the one or more contaminant materials from the chamber for a second duration different than the first duration.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 20: An apparatus, including: a plurality of layers on a substrate, a first subset of the plurality of layers comprising a conductive material and a memory material, and a second subset of the plurality of layers comprising a dielectric material; and a layer of carbon between the conductive material and the memory material within each layer of the first subset of the plurality of layers, the layer of carbon thermally deposited by exposing, in a chamber for each of a quantity of atomic layer deposition (ALD) cycles, exposed areas of the conductive material within the plurality of layers to a carbon-containing precursor and by performing, for each of the quantity of ALD cycles, a purge operation to remove one or more contaminant materials from the chamber.
Aspect 21: The apparatus of aspect 20, where the carbon-containing precursor includes carbon tetrabromide.
Aspect 22: The apparatus of any of aspects 20 through 21, where the conductive material includes tungsten.

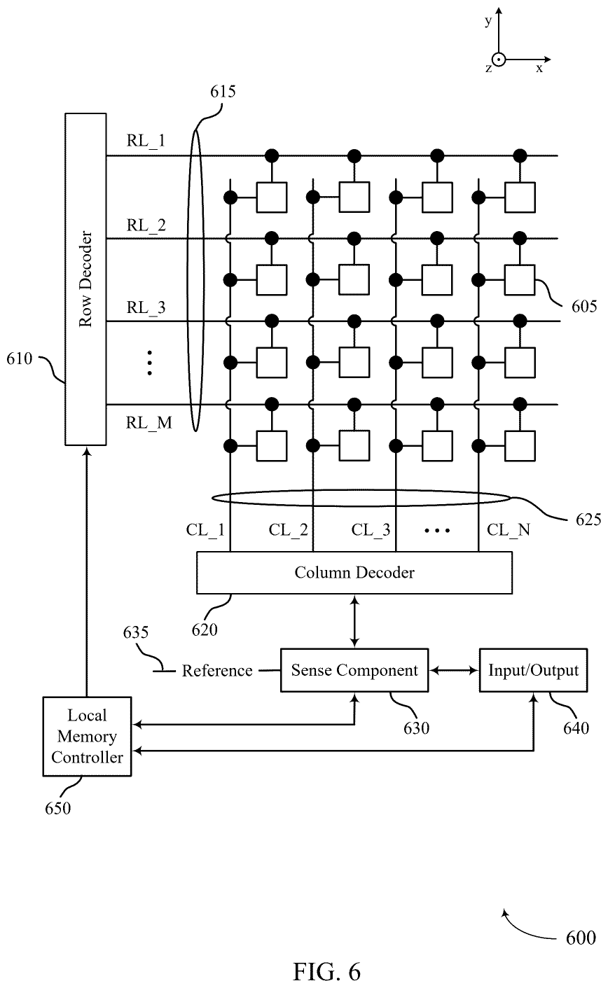

FIG. 6 shows an example of a memory device 600 that supports methods for depositing carbon films using a single precursor in accordance with examples as disclosed herein. In some examples, the memory device 600 may be referred to as or include a memory die, a memory chip, or an electronic memory apparatus. The memory device 600 may be operable to provide locations to store information (e.g., physical memory addresses) that may be used by a system (e.g., a host device coupled with the memory device 600, for writing information, for reading information).

The memory device 600 may include one or more memory cells 605 that each may be programmable to store different logic states (e.g., a programmed one of a set of two or more possible states). For example, a memory cell 605 may be operable to store one bit of information at a time (e.g., a logic 0 or a logic 1). In some examples, a memory cell 605 (e.g., a multi-level memory cell) may be operable to store more than one bit of information at a time (e.g., a logic 00, logic 01, logic 10, a logic 11). In some examples, the memory cells 605 may be arranged in an array.

A memory cell 605 may store a logic state using a configurable material, which may be referred to as a memory element, a storage element, a memory storage element, a material element, a material memory element, a material portion, or a polarity-written material portion, among others. A configurable material of a memory cell 605 may refer to a chalcogenide-based storage component. For example, a chalcogenide storage element may be used in a phase change memory cell, a thresholding memory cell, or a self-selecting memory cell, among other architectures.

In some examples, the material of a memory cell 605 may include a chalcogenide material or other alloy including selenium (Se), tellurium (Te), arsenic (As), antimony (Sb), carbon (C), germanium (Ge), silicon (Si), or indium (In), or various combinations thereof. In some examples, a chalcogenide material having primarily selenium (Se), arsenic (As), and germanium (Ge) may be referred to as a SAG-alloy. In some examples, a SAG-alloy may also include silicon (Si) and such chalcogenide material may be referred to as SiSAG-alloy. In some examples, SAG-alloy may include silicon (Si) or indium (In) or a combination thereof and such chalcogenide materials may be referred to as SiSAG-alloy or InSAG-alloy, respectively, or a combination thereof. In some examples, the chalcogenide material may include additional elements such as hydrogen (H), oxygen (O), nitrogen (N), chlorine (Cl), or fluorine (F), each in atomic or molecular forms.

In some examples, a memory cell 605 may be an example of a phase change memory cell. In such examples, the material used in the memory cell 605 may be based on an alloy (such as the alloys listed above) and may be operated so as to change to different physical state (e.g., undergo a phase change) during normal operation of the memory cell 605. For example, a phase change memory cell 605 may be associated with a relatively disordered atomic configuration (e.g., a relatively amorphous state) and a relatively ordered atomic configuration (e.g., a relatively crystalline state). A relatively disordered atomic configuration may correspond to a first logic state (e.g., a RESET state, a logic 0) and a relatively ordered atomic configuration may correspond to a second logic state (e.g., a logic state different than the first logic state, a SET state, a logic 1).

In some examples (e.g., for thresholding memory cells 605, for self-selecting memory cells 605), some or all of the set of logic states supported by the memory cells 605 may be associated with a relatively disordered atomic configuration of a chalcogenide material (e.g., the material in an amorphous state may be operable to store different logic states). In some examples, the storage element of a memory cell 605 may be an example of a self-selecting storage element. In such examples, the material used in the memory cell 605 may be based on an alloy (e.g., such as the alloys listed above) and may be operated so as to undergo a change to a different physical state during normal operation of the memory cell 605. For example, a self-selecting or thresholding memory cell 605 may have a high threshold voltage state and a low threshold voltage state, where a corresponding “threshold voltage” may refer to a voltage at which or above which the memory cell 605 transitions from a relatively higher-resistance (e.g., non-conductive) state to a relatively lower-resistance (e.g., conductive) state, such as in response to an applied voltage. A high threshold voltage state may correspond to a first logic state (e.g., a RESET state, a logic 0) and a low threshold voltage state may correspond to a second logic state (e.g., a logic state different than the first logic state, a SET state, a logic 1).

During a write operation (e.g., a programming operation) of a self-selecting or thresholding memory cell 605, a polarity used for a write operation may influence (e.g., determine, set, program) a behavior or characteristic of the material of the memory cell 605, such as a thresholding characteristic (e.g., a threshold voltage) of the material. A difference between thresholding characteristics (e.g., resistivity characteristics, conductivity characteristics) of the material of the memory cell 605 for different logic states stored by the material of the memory cell 605 (e.g., a difference between threshold voltages when the material is storing a logic state ‘0’ versus a logic state ‘1’) may correspond to the read window of the memory cell 605.

The memory device 600 may include access lines (e.g., row lines 615 each extending along an illustrative x-direction, column lines 625 each extending along an illustrative y-direction) arranged in a pattern, such as a grid-like pattern. Access lines may be formed with one or more conductive materials. In some examples, row lines 615, or some portion thereof, may be referred to as word lines. In some examples, column lines 625, or some portion thereof, may be referred to as digit lines or bit lines. References to access lines, or their analogues, are interchangeable without loss of understanding. Memory cells 605 may be positioned at intersections of access lines, such as row lines 615 and the column lines 625. In some examples, memory cells 605 may also be arranged (e.g., addressed) along an illustrative z-direction, such as in an implementation of sets of memory cells 605 being located at different levels (e.g., layers, decks, planes, tiers) along the illustrative z-direction. In some examples, a memory device 600 that includes memory cells 605 at different levels may be supported by a different configuration of access lines, decoders, and other supporting circuitry than shown.

Operations such as read operations and write operations may be performed on the memory cells 605 by activating access lines such as one or more of a row line 615 or a column line 625, among other access lines associated with alternative configurations. For example, by activating a row line 615 and a column line 625 (e.g., applying a voltage to the row line 615 or the column line 625), a memory cell 605 may be accessed in accordance with their intersection. An intersection of a row line 615 and a column line 625, among other access lines, in various two-dimensional or three-dimensional configuration may be referred to as an address of a memory cell 605. In some examples, an access line may be a conductive line coupled with a memory cell 605 and may be used to perform access operations on the memory cell 605. In some examples, the memory device 600 may perform operations responsive to commands, which may be issued by a host device coupled with the memory device 600 or may be generated by the memory device 600 (e.g., by a local memory controller 650).

Accessing the memory cells 605 may be controlled through one or more decoders, such as a row decoder 610 or a column decoder 620, among other examples. For example, a row decoder 610 may receive a row address from the local memory controller 650 and activate a row line 615 based on the received row address. A column decoder 620 may receive a column address from the local memory controller 650 and may activate a column line 625 based on the received column address.

The sense component 630 may be operable to detect a state (e.g., a material state, a resistance state, a threshold state) of a memory cell 605 and determine a logic state of the memory cell 605 based on the detected state. The sense component 630 may include one or more sense amplifiers to convert (e.g., amplify) a signal resulting from accessing the memory cell 605 (e.g., a signal of a column line 625 or other access line). The sense component 630 may compare a signal detected from the memory cell 605 to a reference 635 (e.g., a reference voltage, a reference charge, a reference current). The detected logic state of the memory cell 605 may be provided as an output of the sense component 630 (e.g., to an input/output component 640), and may indicate the detected logic state to another component of the memory device 600 or to a host device coupled with the memory device 600.

The local memory controller 650 may control the accessing of memory cells 605 through the various components (e.g., a row decoder 610, a column decoder 620, a sense component 630, among other components). In some examples, one or more of a row decoder 610, a column decoder 620, and a sense component 630 may be co-located with the local memory controller 650. The local memory controller 650 may be operable to receive information (e.g., commands, data) from one or more different controllers (e.g., an external memory controller associated with a host device, another controller associated with the memory device 600), translate the information into a signaling that can be used by the memory device 600, perform one or more operations on the memory cells 605 and communicate data from the memory device 600 to a host device based on performing the one or more operations. The local memory controller 650 may generate row address signals and column address signals to activate access lines such as a target row line 615 and a target column line 625. The local memory controller 650 also may generate and control various signals (e.g., voltages, currents) used during the operation of the memory device 600. In general, the amplitude, the shape, or the duration of an applied signal discussed herein may be varied and may be different for the various operations discussed in operating the memory device 600.

The local memory controller 650 may be operable to perform one or more access operations on one or more memory cells 605 of the memory device 600. Examples of access operations may include a write operation, a read operation, a refresh operation, a precharge operation, or an activate operation, among others. In some examples, access operations may be performed by or otherwise coordinated by the local memory controller 650 in response to access commands (e.g., from a host device). The local memory controller 650 may be operable to perform other access operations not listed here or other operations related to the operating of the memory device 600 that are not directly related to accessing the memory cells 605.

The memory device 600 may be an example of the electronic device, as described herein with reference to FIGS. 1 through 5. For example, the techniques disclosed herein describe precursors capable of being used in ALD to produce one or more layers of carbon with the purity above the threshold amount for the memory device 600. The layer of carbon may function as a conductive component of the memory device 600, such as a portion of an element such as a transistor, a capacitor, or memory cell 605. For example, the layer of carbon may form an electrode, an etch-stop material, a gate, a barrier material, or a spacer material associated with the memory device 600. To produce such layers of carbon, ALD may be performed by reacting a single precursor with a base material over multiple ALD cycles to thermally deposit a layer of carbon on the base material. For instance, each of the ALD cycles may include reacting a carbon-containing precursor with the base material in a chamber and performing a purge operation to remove contaminant materials (e.g., side products of the reaction, at least portions of the single precursor) from the chamber. By performing ALD with a single precursor, a carbon layer may be formed with purity above the threshold amount for the memory device 600, which may increase a conductivity of carbon films within the memory device 600, thereby increasing reliability and accuracy of operations (e.g., access operations) performed by the memory device 600 in accordance with its intended function.

The memory device 600 may include any quantity of non-transitory computer readable media that support methods for depositing carbon films using a single precursor, a row decoder 610, a column decoder 620, a sense component 630, or an input/output component 640, or any combination thereof may include or may access one or more non-transitory computer readable media storing instructions (e.g., firmware) for performing the functions ascribed herein to the memory device 600. For example, such instructions, if executed by the memory device 600, may cause the memory device 600 to perform one or more associated functions as described herein.

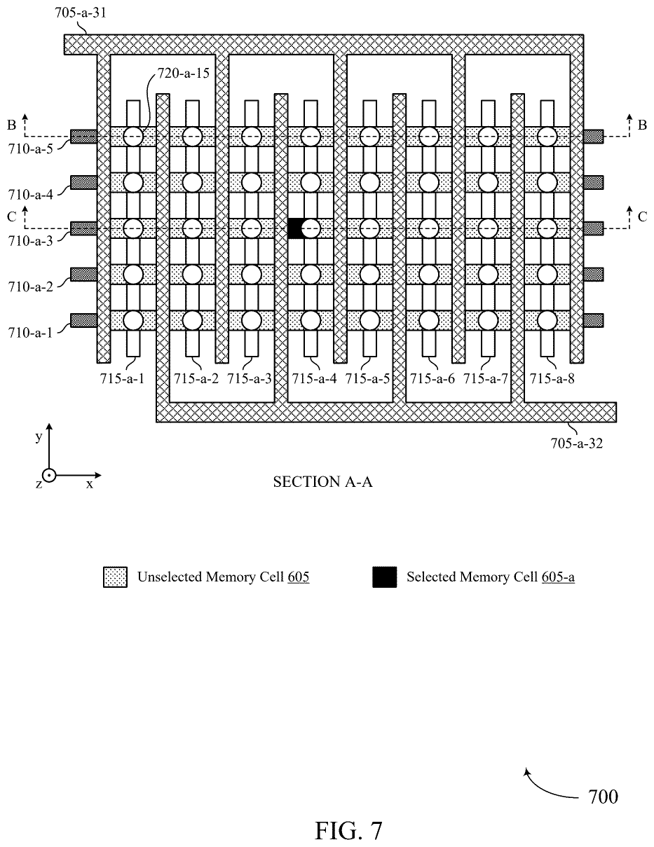

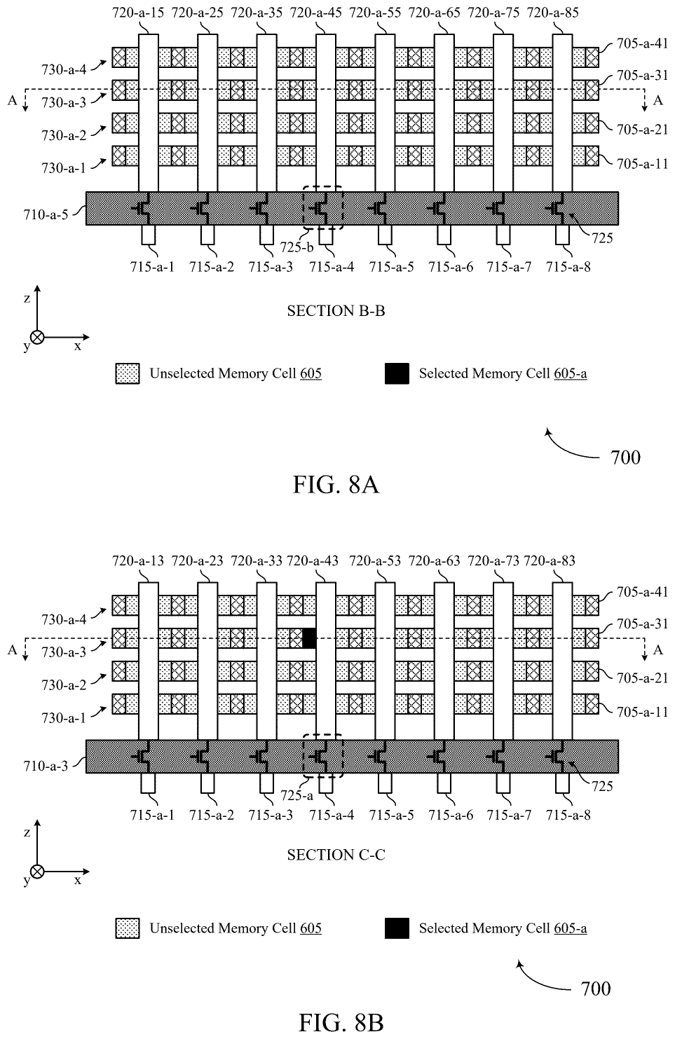

FIGS. 7, 8A, and 8B show an example of a memory array 700 that supports methods for depositing carbon films using a single precursor in accordance with examples as disclosed herein. The memory array 700 may be included in a memory device 600, and illustrates an example of a three-dimensional arrangement of memory cells 605 that may be accessed by various conductive structures (e.g., access lines). FIG. 7 illustrates a top section view (e.g., SECTION A-A) of the memory array 700 relative to a cut plane A-A as shown in FIGS. 8A and 8B. FIG. 8A illustrates a side section view (e.g., SECTION B-B) of the memory array 700 relative to a cut plane B-B as shown in FIG. 7. FIG. 8B illustrates a side section view (e.g., SECTION C-C) of the memory array 700 relative to a cut plane C-C as shown in FIG. 7. The section views may be examples of cross-sectional views of the memory array 700 with some aspects (e.g., dielectric structures) removed for clarity. Elements of the memory array 700 may be described relative to an x-direction, a y-direction, and a z-direction, as illustrated in each of FIGS. 7, 8A, and 8B. Although some elements included in FIGS. 7, 8A, and 8B are labeled with a numeric indicator, other corresponding elements are not labeled, although they are the same or would be understood to be similar, in an effort to increase visibility and clarity of the depicted features. Further, although some quantities of repeated elements are shown in the illustrative example of memory array 700, techniques in accordance with examples as described herein may be applicable to any quantity of such elements, or ratios of quantities between one repeated element and another.

In the example of memory array 700, memory cells 605 and word lines 705 may be distributed along the z-direction according to levels 730 (e.g., decks, layers, planes, tiers, as illustrated in FIGS. 8A and 8B). In some examples, the z-direction may be orthogonal to a substrate (not shown) of the memory array 700, which may be below the illustrated structures along the z-direction. Although the illustrative example of memory array 700 includes four levels 730, a memory array 700 in accordance with examples as disclosed herein may include any quantity of one or more levels 730 (e.g., 64 levels, 128 levels) along the z-direction.

Each word line 705 may be an example of a portion of an access line that is formed by one or more conductive materials (e.g., one or more metal portions, one or more metal alloy portions). As illustrated, a word line 705 may be formed in a comb structure, including portions (e.g., projections, tines) extending along the y-direction through gaps (e.g., alternating gaps) between pillars 720. For example, as illustrated, the memory array 700, may include two word lines 705 per level 730 (e.g., according to odd word lines 705-a-n1 and even word lines 705-a-n2 for a given level, n), where such word lines 705 of the same level 730 may be described as being interleaved (e.g., with portions of an odd word line 705-a-n1 projecting along the y-direction between portions of an even word line 705-a-n2, and vice versa). In some examples, an odd word line 705 (e.g., of a level 730) may be associated with a first memory cell 605 on a first side (e.g., along the x-direction) of a given pillar 720 and an even word line (e.g., of the same level 730) may be associated with a second memory cell 605 on a second side (e.g., along the x-direction, opposite the first memory cell 605) of the given pillar 720. Thus, in some examples, memory cells 605 of a given level 730 may be addressed (e.g., selected, activated) in accordance with an even word line 705 or an odd word line 705.

Each pillar 720 may be an example of a portion of an access line (e.g., a conductive pillar portion) that is formed by one or more conductive materials (e.g., one or more metal portions, one or more metal alloy portions). As illustrated, the pillars 720 may be arranged in a two-dimensional array (e.g., in an xy-plane) having a first quantity of pillars 720 along a first direction (e.g., eight pillars along the x-direction, eight rows of pillars), and having a second quantity of pillars 720 along a second direction (e.g., five pillars along the y-direction, five columns of pillars). Although the illustrative example of memory array 700 includes a two-dimensional arrangement of eight pillars 720 along the x-direction and five pillars 720 along the y-direction, a memory array 700 in accordance with examples as disclosed herein may include any quantity of pillars 720 along the x-direction and any quantity of pillars 720 along the y-direction. Further, as illustrated, each pillar 720 may be coupled with a respective set of memory cells 605 (e.g., along the z-direction, one or more memory cells 605 for each level 730). A pillar 720 may have a cross-sectional area in an xy-plane that extends along the z-direction. Although illustrated with a circular cross-sectional area in the xy-plane, a pillar 720 may be formed with a different shape, such as having an elliptical, square, rectangular, polygonal, or other cross-sectional area in an xy-plane.

The memory cells 605 each may include a chalcogenide material. In some examples, the memory cells 605 may be examples of thresholding memory cells. Each memory cell 605 may be accessed (e.g., addressed, selected) according to an intersection between a word line 705 (e.g., a level selection, which may include an even or odd selection within a level 730) and a pillar 720. For example, as illustrated, a selected memory cell 605-a of the level 730-a-3 may be accessed according to an intersection between the pillar 720-a-43 and the word line 705-a-32.

A memory cell 605 may be accessed (e.g., written to, read from) by applying an access bias (e.g., an access voltage, V_{access}, which may be a positive voltage or a negative voltage) across the memory cell 605. In some examples, an access bias may be applied by biasing a selected word line 705 with a first voltage (e.g., V_{access}/2) and by biasing a selected pillar 720 with a second voltage (e.g., −V_{access}/2), which may have an opposite sign relative to the first voltage. Regarding the selected memory cell 605-a, a corresponding access bias (e.g., the first voltage) may be applied to the word line 705-a-32, while other unselected word lines 705 may be grounded (e.g., biased to 0V). In some examples, a word line bias may be provided by a word line driver (not shown) coupled with one or more of the word lines 705.

To apply a corresponding access bias (e.g., the second voltage) to a pillar 720, the pillars 720 may be configured to be selectively coupled with a sense line 715 (e.g., a digit line, a column line, an access line extending along the y-direction) via a respective transistor 725 coupled between (e.g., physically, electrically) the pillar 720 and the sense line 715. In some examples, the transistors 725 may be vertical transistors (e.g., transistors having a channel along the z-direction, transistors having a semiconductor junction along the z-direction), which may be formed above the substrate of the memory array 700 using various techniques (e.g., thin film techniques). In some examples, a selected pillar 720, a selected sense line 715, or a combination thereof may be an example of a selected column line 625 described with reference to FIG. 6 (e.g., a bit line).

The transistors 725 (e.g., a channel portion of the transistors 725) may be activated by gate lines 710 (e.g., activation lines, selection lines, a row line, an access line extending along the x-direction) coupled with respective gates of a set of the transistors 725 (e.g., a set along the x-direction). In other words, each of the pillars 720 may have a first end (e.g., towards the negative z-direction, a bottom end) configured for coupling with an access line (e.g., a sense line 715). In some examples, the gate lines 710, the transistors 725, or both may be considered to be components of a row decoder 610 (e.g., as pillar decoder components). In some examples, the selection of (e.g., biasing of) pillars 720, or sense lines 715, or various combinations thereof, may be supported by a column decoder 620, or a sense component 630, or both.

To apply the corresponding access bias (e.g., −V_{access}/2) to the pillar 720-a-43, the sense line 715-a-4 may be biased with the access bias, and the gate line 710-a-3 may be grounded (e.g., biased to 0V) or otherwise biased with an activation voltage. In an example where the transistors 725 are n-type transistors, the gate line 710-a-3 being biased with a voltage that is relatively higher than the sense line 715-a-4 may activate the transistor 725-a (e.g., cause the transistor 725-a to operate in a conducting state), thereby coupling the pillar 720-a-43 with the sense line 715-a-4 and biasing the pillar 720-a-43 with the associated access bias. However, the transistors 725 may include different channel types, or may be operated in accordance with different biasing schemes, to support various access operations.

In some examples, unselected pillars 720 of the memory array 700 may be electrically floating when the transistor 725-a is activated, or may be coupled with another voltage source (e.g., grounded, via a high-resistance path, via a leakage path) to avoid a voltage drift of the pillars 720. For example, a ground voltage being applied to the gate line 710-a-3 may not activate other transistors coupled with the gate line 710-a-3, because the ground voltage of the gate line 710-a-3 may not be greater than the voltage of the other sense lines 715 (e.g., which may be biased with a ground voltage or may be floating). Further, other unselected gate lines 710, including gate line 710-a-5 as shown in FIG. 8A, may be biased with a voltage equal to or similar to an access bias (e.g., −V_{access}/2, or some other negative bias or bias relatively near the access bias voltage), such that transistors 725 along an unselected gate line 710 are not activated. Thus, the transistor 725-b coupled with the gate line 710-a-5 may be deactivated (e.g., operating in a non-conductive state), thereby isolating the voltage of the sense line 715-a-4 from the pillar 720-a-45, among other pillars 720.

In a write operation, a memory cell 605 may be written to by applying a write bias (e.g., where V_{access}=V_{write}, which may be a positive voltage or a negative voltage) across the memory cell 605. In some examples, a polarity of a write bias may influence (e.g., determine, set, program) a behavior or characteristic of the material of the memory cell 605, such as the threshold voltage of the material. For example, applying a write bias with a first polarity may set the material of the memory cell 605 with a first threshold voltage, which may be associated with storing a logic 0. Further, applying a write bias with a second polarity (e.g., opposite the first polarity) may set the material of the memory cell with a second threshold voltage, which may be associated with storing a logic 1. A difference between threshold voltages of the material of the memory cell 605 for different logic states stored by the material of the memory cell 605 (e.g., a difference between threshold voltages when the material is storing a logic state ‘0’ versus a logic state ‘1’) may correspond to the read window of the memory cell 605.

In a read operation, a memory cell 605 may be read from by applying a read bias (e.g., where V_{access}=V_{read}, which may be a positive voltage or a negative voltage) across the memory cell 605. In some examples, a logic state of the memory cell 605 may be evaluated based on whether the memory cell 605 thresholds (e.g., transitions to a relatively lower-resistance or conductive state, permits current) in the presence of the applied read bias. For example, such a read bias may cause a memory cell 605 storing a first logic state (e.g., a logic 0) to threshold (e.g., permit a current flow, permit a current above a threshold current), and may not cause a memory cell 605 storing a second logic state (e.g., a logic 1) to threshold (e.g., may not permit a current flow, may permit a current below a threshold current).

The memory array 700 may be an example of the electronic device, as described herein with reference to FIGS. 1 through 6. For example, the techniques disclosed herein describe precursors capable of being used in ALD to produce one or more layers of carbon with the purity above the threshold amount for the memory array 700. The layer of carbon may function as a conductive component of the memory array 700, such as a portion of an element such as a transistor, a capacitor, or memory cell 605. For example, the layer of carbon may form an electrode, an etch-stop material, a gate, a barrier material, or a spacer material associated with the memory array 700. To produce such layers of carbon, ALD may be performed by reacting a single precursor with a base material over multiple ALD cycles to thermally deposit a layer of carbon on the base material. For instance, each of the ALD cycles may include reacting a carbon-containing precursor with the base material in a chamber and performing a purge operation to remove contaminant materials (e.g., side products of the reaction, at least portions of the single precursor) from the chamber. By performing ALD with a single precursor, a carbon layer may be formed with purity above the threshold amount for the memory array 700, which may increase a conductivity of carbon films within the memory array 700, thereby increasing reliability and accuracy of operations (e.g., access operations) performed by or with the memory array 700 in accordance with its intended function.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99% met, or at least 99.9% met.

As used herein, spatially relative terms, such as “adjacent,” “beneath,” “below,” “lower,” “bottom,” “above,” “upper,” “top,” “front,” “rear,” “left,” “right,” and the like, may be used for case of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one or ordinary skill in the art. The materials may be otherwise oriented (e.g., rotated 90 degrees, inverted, flipped), and the spatially relative descriptors used herein interpreted accordingly.

As used herein, the term “electronic device” may include, without limitation, a memory device, as well as semiconductor devices, which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may be a 3D electronic device, such as a 3D dynamic random access memory (DRAM) memory device, a 3D crosspoint memory device, or a 3D phase-change random access memory (PCRAM) memory device.

As used herein, the term “substrate” means and includes a foundation material or construction upon which components, such as those within a semiconductor device or electronic device are formed. The substrate may be a semiconductor substrate, a base material, a base semiconductor material on a supporting structure, a metal electrode, or a semiconductor substrate having one or more materials, structures, or regions formed thereon. The substrate may be a conventional silicon substrate, or other bulk substrate including a semiconductive material. As used herein, the term “bulk substrate” means and includes not only silicon wafers, but also silicon-on insulator (“SOI”) substrates, such as silicon-on-sapphire (“SOS”) substrates or silicon-on-glass (“SOG”) substrates, epitaxial layers of silicon on a base semiconductor foundation, or other semiconductor or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. Furthermore, when reference is made to a “substrate” in the following description, previous process stages may have been utilized to form materials, regions, or junctions in or on the base semiconductor structure or foundation.

The terms “layer” and “level” used herein refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or any type of processor. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
performing one or more atomic layer deposition (ALD) cycles to thermally deposit a layer of carbon on a base material, each of the one or more ALD cycles comprising:
reacting a carbon-containing precursor with the base material in a chamber; and
performing a purge operation to remove one or more contaminant materials from the chamber, the one or more contaminant materials based at least in part on reacting the carbon-containing precursor with the base material.

2. The method of claim 1, wherein reacting the carbon-containing precursor with the base material comprises:
inserting the carbon-containing precursor to the chamber with the base material and a carrier gas, wherein the carbon-containing precursor is associated with a first partial pressure and the carrier gas is associated with a second partial pressure different from the first partial pressure.

3. The method of claim 1, wherein reacting the carbon-containing precursor with the base material comprises conducting the reacting at a temperature at or above 280° C.

4. The method of claim 3, wherein the temperature is at or below 550° C.

5. The method of claim 1, wherein reacting the carbon-containing precursor with the base material is based at least in part on a concentration of the carbon-containing precursor.

6. The method of claim 1, wherein each of the one or more ALD cycles comprises:
reacting the carbon-containing precursor with the base material for a first duration; and
performing the purge operation to remove the one or more contaminant materials for a second duration different than the first duration.

7. The method of claim 6, wherein over the first duration, a ratio between a first amount of the carbon-containing precursor that is reacted with the base material and a second amount of the one or more contaminant materials satisfies a threshold.

8. The method of claim 1, wherein the layer of carbon forms one or more sp² bonds with the base material based at least in part on reacting the carbon-containing precursor with the base material.

9. The method of claim 1, wherein each of the one or more ALD cycles consists of reacting the carbon-containing precursor with the base material in the chamber and performing the purge operation to remove the one or more contaminant materials from the chamber.

10. The method of claim 1, wherein the one or more ALD cycles are based at least in part on a thermal ALD process.

11. The method of claim 1, wherein the carbon-containing precursor comprises carbon tetrabromide.

12. The method of claim 1, wherein the base material comprises tungsten.

13. The method of claim 1, wherein the one or more contaminant materials comprise bromine and exclude silicon, oxygen, and hydrogen.

14. A method, comprising:
forming a plurality of layers on a substrate, a first subset of the plurality of layers comprising a conductive material and a second subset of the plurality of layers comprising a dielectric material;
forming a cavity in the plurality of layers to expose one or more first surfaces of the conductive material and one or more second surfaces of the dielectric material;
exposing, in a chamber for each of a quantity of atomic layer deposition (ALD) cycles, the one or more first surfaces and the one or more second surfaces to a carbon-containing precursor, wherein a layer of carbon is thermally deposited on the one or more first surfaces of the conductive material, and wherein the layer of carbon is not deposited on the one or more second surfaces of the dielectric material; and
performing, for each of the quantity of ALD cycles, a purge operation to remove one or more contaminant materials from the chamber, the one or more contaminant materials based at least in part on exposing the one or more first surfaces and the one or more second surfaces to the carbon-containing precursor.

15. The method of claim 14, wherein exposing the one or more first surfaces and the one or more second surfaces to the carbon-containing precursor comprises:
inserting the carbon-containing precursor to the chamber with the one or more first surfaces and the one or more second surfaces and a carrier gas, wherein the carbon-containing precursor is associated with a first partial pressure and the carrier gas is associated with a second partial pressure different from the first partial pressure.

16. The method of claim 14, wherein exposing the one or more first surfaces and the one or more second surfaces to the carbon-containing precursor comprises exposing the one or more first surfaces and the one or more second surfaces in the chamber to a temperature at or above 280° C.

17. The method of claim 16, wherein the temperature is at or below 550° C.

18. The method of claim 14, wherein exposing the one or more first surfaces and the one or more second surfaces to the carbon-containing precursor is based at least in part on a concentration of the carbon-containing precursor.

19. The method of claim 14, wherein each of the quantity of ALD cycles comprises:
reacting the carbon-containing precursor with the one or more first surfaces of the conductive material in the chamber for a first duration; and
performing the purge operation to remove the one or more contaminant materials from the chamber for a second duration different than the first duration.

20. An apparatus, comprising:
a plurality of layers on a substrate, a first subset of the plurality of layers comprising a conductive material and a memory material, and a second subset of the plurality of layers comprising a dielectric material; and
a layer of carbon between the conductive material and the memory material within each layer of the first subset of the plurality of layers, the layer of carbon thermally deposited by exposing, in a chamber for each of a quantity of atomic layer deposition (ALD) cycles, exposed areas of the conductive material within the plurality of layers to a carbon-containing precursor and by performing, for each of the quantity of ALD cycles, a purge operation to remove one or more contaminant materials from the chamber.

21. The apparatus of claim 20, wherein the carbon-containing precursor comprises carbon tetrabromide.

22. The apparatus of claim 20, wherein the conductive material comprises tungsten.
